(19) United States
(12) Patent Application Publication
(10) Pub. No.: US 2017/0324381 A1
(43) Pub. Date: Nov. 9, 2017

(54) TRANSFORMER, POWER MATCHING NETWORK AND DIGITAL POWER AMPLIFIER

(71) Applicant: Huawei Technologies Co., Ltd., Shenzhen (CN)

(72) Inventors: Huizhen QIAN, Chengdu (CN); Xun LUO, Delft (NL); Robert Bogdan STASZEWSKI, Delft (NL)

(21) Appl. No.: 15/661,731

(22) Filed: Jul. 27, 2017

Related U.S. Application Data
(63) Continuation of application No. PCT/EP2015/051576, filed on Jan. 27, 2015.

(51) Int. Cl. H03F 1/22; H03H 7/38; H03F 3/193; H03F 1/56; H01F 19/08; H03F 3/21; H03H 7/42; H01F 27/28

(52) U.S. Cl. CPC H03F 1/223; H03H 7/42; H03H 7/38; H03F 3/193; H01F 27/2804; H03F 1/56; H01F 19/08; H03F 3/211; H01F 2027/2819; H01F 2027/2809; H03F 2200/451; H03F 2200/541

(57) ABSTRACT

A transformer includes: a primary winding comprising a first port, a second port and a metal layer connected between the first port and the second port, the metal layer comprising a plurality of sections of different electrical lengths and/or characteristic impedances; and a secondary winding electromagnetically coupled with the primary winding, the secondary winding comprising a first port, a second port and a metal layer connected between the first port and the second port, the metal layer comprising a plurality of sections of different electrical lengths and/or characteristic impedances.

### CROSS-REFERENCE TO RELATED APPLICATIONS

This application is a continuation of International Application No. PCT/EP2015/051576, filed on Jan. 27, 2015, the disclosure of which is hereby incorporated by reference in its entirety.

### TECHNICAL FIELD

The present disclosure relates to a transformer, a power matching network for use in a power amplifier, the power matching network including such transformer and other matching components, in particular an ultra-wideband digital power amplifier.

### BACKGROUND

Multiple communications standards utilize wideband power amplifiers with compact size and high power efficiency. Currently a lot of wideband PA design solutions are used such as distributed amplifier, balanced amplifier, high-order output matching amplifier and tunable amplifier. Such solutions, however, have the following problems. The distributed PA usually has poor impedance matching, thus it has low power efficiency. The balanced PA could achieve good input/output matching over wideband. However, it needs couplers to separate the input signal into the sub-amplifiers and combine the output power, which are complex especially when the sub-amplifiers number is increasing, thereby increasing both passive loss and chip area. The synthesized high-order output matching amplifier needs multiple inductors in the output and inter-stage matching circuits, it also increases both the passive power loss and chip area. The tunable amplifier of compact size uses low-quality-factor active circuits in the matching network to achieve wide operation band, which degrades the efficiency.

There is a need to provide a compact design for a power-efficient wideband power amplifier.

### SUMMARY

It is the object of the disclosure to provide a solution for improving the power efficiency of wideband power amplifiers with compact size.

This object is achieved by the features of the independent claims. Further implementation forms are apparent from the dependent claims, the description and the figures.

The basic concept described in this disclosure is the introduction of a compact power amplifier output matching network with a stacked stepped-impedance (SSI) transformer to improve the power efficiency while tracking optimum load impedance within a wide bandwidth. This solution has significant advantages that are wide bandwidth, high efficiency, and compact size. The SSI transformer can be applied in various wide-band matching networks to improve power efficiency with compact size, such as class-A, class-B, class-AB, class-C, class-D, class-E, class-E⁻¹, class-F, class-F⁻¹, class-G, etc. The stacked stepped-impedance (SSI) transformer has some characteristics. First, it is formed by stepped-impedance inductors. Second, the primary and secondary windings may be located at different metals; different windings may be stacked coupled. Third, primary or secondary windings can employ parallel windings, which further improve the coupling factor and Q (quality factor).

In order to describe the disclosure in detail, the following terms, abbreviations and notations will be used:

PA: power amplifier
DPA: digital power amplifier
SSI: stacked stepped impedance
Z: characteristic impedance
Θ: electrical length
Q: quality factor
M: metal layer
RF: radio frequency

In the following, electrical circuits and transformers characterized by characteristic impedance, electrical length and quality factor are described. The characteristic impedance of a uniform transmission line is the ratio of the amplitudes of voltage and current of a single wave propagating along the line, that is, a wave travelling in one direction in the absence of reflections in the other direction. The characteristic impedance is determined by the geometry and materials of the transmission line. For a uniform line, the characteristic impedance is not depending on its length. The electrical length refers to the length of an electrical conductor in terms of the phase shift introduced by transmission over that conductor at some frequency. The quality factor or Q factor is a dimensionless parameter that describes how under-damped an oscillator or resonator is, or equivalently, characterizes a resonator's bandwidth relative to its center frequency. A higher Q indicates a lower rate of energy loss relative to the stored energy of the resonator, i.e., the oscillations die out more slowly.

In the following, transformers for use in class D amplifiers and class E amplifiers are described. A class-D amplifier is an electronic amplifier in which the amplifying devices, e.g. transistors, usually implemented by MOSFETs, operate as electronic switches, instead of as linear gain devices. The signal to be amplified is a train of constant amplitude pulses, so the active devices switch rapidly back and forth between a fully conductive and nonconductive state. In a Class-E amplifier, the transistor operates as an on/off switch and the load network shapes the voltage and current waveforms to prevent simultaneous high voltage and high current in the transistor. This operation minimizes power dissipation, especially during the switching transitions.

According to a first aspect, the disclosure relates to a transformer, comprising: a primary winding comprising a first port, a second port and a metal layer connected between the first port and the second port, the metal layer comprising a plurality of sections of different widths; and a secondary winding electromagnetically coupled with the primary winding, the secondary winding comprising a first port, a second port and a metal layer connected between the first port and the second port, the metal layer comprising a plurality of sections of different widths.

When using the transformer in a power amplifier, the power amplifier can be realized in a power efficient manner using a compact design. The implementation of the two windings by metal layers having multiple sections of different widths provides a compact design for a power-efficient wideband power amplifier.

In a first possible implementation form of the transformer according to the first aspect, the primary winding and the secondary winding are stacked coupled by having at least a main portion of the secondary winding arranged under or above the primary winding.

By using the stack coupling high quality factors can be provided at small space. Hence, the design of the power amplifier can be realized in a compact manner.

In a second possible implementation form of the transformer according to the first aspect, the primary winding and the secondary winding are planar coupled by having both windings on the same plane.

By using the planar coupling, the transformer can be manufactured in an efficient fashion.

In a third possible implementation form of the transformer according to the first aspect as such or according to any of the preceding implementation forms of the first aspect, at least one of the primary winding or the secondary winding comprises an auxiliary winding arranged in parallel with the at least one of the primary winding or the secondary winding.

Using such auxiliary winding improves the coupling factor between the two windings and also the quality factor of the inductor.

In a fourth possible implementation form of the transformer according to the first aspect as such or according to any of the preceding implementation forms of the first aspect, each section of the plurality of sections of the metal layer of the primary winding and/or the secondary winding has a different local characteristic impedance.

This design introduces more freedom to tune the inductance with the same circuit size and achieves an improved quality factor.

In a fifth possible implementation form of the transformer according to the first aspect as such or according to any of the preceding implementation forms of the first aspect, each section of the plurality of sections of the metal layer of the primary winding and/or the secondary winding has a different or same electrical length.

This design introduces more freedom to tune the inductance with the same circuit size and achieves an improved quality factor.

In a sixth possible implementation form of the transformer according to the first aspect as such or according to any of the preceding implementation forms of the first aspect, the metal layer of the primary winding is arranged on a single plane and/or the metal layer of the secondary winding is arranged on a single plane.

By arranging the metal layer of the primary winding and/or the metal layer of the secondary winding on a single plane the chip design can be facilitated and the transformer can be efficiently manufactured.

In a seventh possible implementation form of the transformer according to the first aspect as such or according to any of the preceding implementation forms of the first aspect, the metal layer of the primary winding is arranged symmetrically with respect to the first port and the second port of the primary winding, in particular symmetrically with respect to a perpendicular bisector of the first port and the second port of the primary winding; and/or the metal layer of the secondary winding is arranged symmetrically with respect to the first port and the second port of the secondary winding, in particular symmetrically with respect to a perpendicular bisector of the first port and the second port of the secondary winding.

By having such symmetrical design, the transformer's transmission line model can be easily derived and the design provides a high degree of flexibility and accuracy, the transformer is suitable for differential PA circuit design.

In an eighth possible implementation form of the transformer according to the seventh implementation form of the first aspect, each section of the metal layer of the primary winding comprises a first subsection and a second subsection of the same width, the first subsection and the second subsection arranged symmetrically with respect to the first port and the second port of the primary winding; and/or each section of the metal layer of the secondary winding comprises a first subsection and a second subsection of the same width, the first subsection and the second subsection arranged symmetrically with respect to the first port and the second port of the secondary winding.

By using two symmetrically designed subsections of equal width, the transformer can be designed in a compact manner while providing an improved quality factor for differential PA matching network.

In a ninth possible implementation form of the transformer according to the third implementation form of the first aspect, the metal layer of the auxiliary winding is arranged on the same metal layer of a main winding of the at least one of the primary winding or the secondary winding.

By such arrangement the Q factor of the transformer can be improved.

In a tenth possible implementation form of the transformer according to the third implementation form of the first aspect, the auxiliary winding of the at least one of the primary winding or secondary winding is arranged inside a main winding of the at least one of the primary winding or the secondary winding.

By such design the magnetic coupling between the primary winding and secondary winding and hence the coupling factor k is improved.

In an eleventh possible implementation form of the transformer according to the seventh implementation form of the first aspect, two turns of the main winding of the secondary winding are arranged at the top edge of the main winding of the primary winding.

By such design the magnetic coupling between the primary winding and secondary winding comes from both horizontal and vertical directions. This further improves the coupling factor k between the two windings to promote wideband operation.

In a twelfth possible implementation form of the transformer according to the first aspect as such or according to any of the preceding implementation forms of the first aspect, the metal layer of the primary winding comprises sections of four different widths; the metal layer of the secondary winding is formed by a main winding of three different characteristic impedances and four different electrical lengths and a parallel auxiliary winding of two different characteristic impedances and two different electrical lengths, the main winding of the secondary winding stacked under the primary winding and the auxiliary winding of the secondary winding located inside the primary winding.

Such design has shown to provide optimal results with respect to coupling efficiency over a large frequency range at compact design and also improved quality factor.

According to a second aspect, the disclosure relates to a power matching network, the power matching network comprising: a transformer according to the first aspect as such or according to any of the implementation forms of the first aspect; a pair of input capacitances, each input capacitance coupled to a respective port of the primary winding; and an output capacitance coupled between a first port and a second port of the secondary winding.

Such a power matching network can replace the classical class-E matching network thereby minimizing the number of passive components. Only three fixed passive components are needed in this matching network, i.e. input capacitance Cₚ (including parasitic capacitance of switch device), output capacitance Cₒᵤₜ and the SSI transformer. The wideband fundamental resonant tank is absorbed into the power matching network to allow the current of fundamental frequency to pass. The power matching network can be used in any types of power amplifiers.

According to a third aspect, the disclosure relates to a digital power amplifier, comprising: a power matching network according to the second aspect; and a differential cascode switch mode transistor array coupled to the first port and the second port of the primary winding, wherein a load is connectable to the first port and the second port of the secondary winding.

In such a digital power amplifier, the SSI transformer of the power matching network performs the impedance transformation from the optimum load of the active circuits to the antenna load, while combining all the DPA cells current and acting as part of the band-pass matching network. The SSI transformer can be implemented with low insertion loss and high inductance ratio within a wide operation band to realize a broad-band DPA with high efficiency and high output power.

According to a fourth aspect, the disclosure relates to an inductor, comprising: a first port, a second port and a metal layer connected between the first port and the second port, the metal layer comprising a plurality of sections of different widths.

Such an inductor when used in a transformer provides a compact design for the transformer. When using the transformer in a power amplifier, the power amplifier can be realized in a power efficient manner using a compact design. The implementation of the two windings by metal layers having multiple sections of different widths provides a compact design for a power-efficient wideband power amplifier.

In a first possible implementation form of the inductor according to the fourth aspect, each section of the plurality of sections of the metal layer has a different local characteristic impedance.

This design introduces more freedom to tune the inductance with the same circuit size and achieves an improved quality factor.

In a second possible implementation form of the inductor according to the fourth aspect as such or according to the first implementation form of the first aspect, each section of the plurality of sections of the metal layer has a different electrical length.

This design introduces more freedom to tune the inductance with the same circuit size and achieves an improved quality factor.

In a third possible implementation form of the inductor according to the fourth aspect as such or according to any of the preceding implementation forms of the first aspect, the metal layer is arranged on a single plane.

By arranging the metal layer of the inductor on a single plane a chip design using such inductor can be facilitated and a transformer using such inductors can be efficiently manufactured.

In a fourth possible implementation form of the inductor according to the fourth aspect as such or according to any of the preceding implementation forms of the first aspect, the metal layer is arranged symmetrically with respect to the first port and the second port, in particular symmetrically with respect to a perpendicular bisector of the first port and the second port.

By having such symmetrical design, the inductors transmission line model can be easily derived and the design provides a high degree of flexibility and accuracy, the transformer is suitable for differential PA circuit design.

In a fifth possible implementation form of the inductor according to the fourth aspect as such or according to any of the preceding implementation forms of the first aspect, each section comprises a first subsection and a second subsection of the same width, the first subsection and the second subsection arranged symmetrically with respect to the first port and the second port.

By using two symmetrically designed subsections of equal width, the inductor can be designed in a compact manner while providing an improved quality factor.

In a sixth possible implementation form of the inductor according to the fourth aspect as such or according to any of the preceding implementation forms of the first aspect, the metal layer comprises a branch-off, the branch off having a different width than the sections of the metal layer.

By using such branch-off as additional section at different width, the design of the inductor can be provided an improved quality factor.

According to a fifth aspect, the disclosure relates to a transformer, comprising: a primary winding; and a secondary winding electromagnetically coupled with the primary winding, wherein at least one of the primary winding and the secondary winding comprises an inductor according to the fourth aspect as such or according to any of the implementation forms of the fourth aspect.

When using the transformer in a power amplifier, the power amplifier can be realized in a power efficient manner using a compact design. The implementation of the two windings by metal layers having multiple sections of different widths provides a compact design for a power-efficient wideband power amplifier.

In a first possible implementation form of the transformer according to the fifth aspect, both windings comprise an inductor according to the fourth aspect as such or according to any of the implementation forms of the fourth aspect, the metal layers of the two inductors arranged at different planes.

When arranging the metal layers of the two inductors at different planes the coupling is performed in horizontal and vertical direction thus improving the coupling factor k and the quality factor Q.

In a second possible implementation form of the transformer according to the fifth aspect as such or according to the first implementation form of the fifth aspect, the primary winding and the secondary winding are stacked coupled by having the secondary winding arranged under or above the primary winding.

When arranging the secondary winding arranged under or above the primary winding the coupling is performed in horizontal and vertical direction thus improving the coupling factor k and the quality factor Q.

In a third possible implementation form of the transformer according to the fifth aspect as such or according to any of the preceding implementation forms of the fifth aspect, at least one of the two windings comprises a main winding and at least one auxiliary winding arranged in parallel with the main winding.

Using an auxiliary winding parallel with the main winding further improves the quality factor of the transformer.

In a fourth possible implementation form of the transformer according to the third implementation form of the fifth aspect, the at least one auxiliary winding of the secondary winding and the main winding of the primary winding are arranged on a first plane and the main winding of the secondary winding is arranged on a second plane located under or above the first plane.

By such a design the coupling is performed in horizontal and vertical direction thus improving the coupling factor k and the quality factor Q.

In a fifth possible implementation form of the transformer according to the fourth implementation form of the fifth aspect, the at least one auxiliary winding of the secondary winding is arranged inside the main winding of the primary winding.

Arranging the auxiliary winding inside the main winding results in a very compact design while improving the coupling factor k of the transformer.

In a sixth possible implementation form of the transformer according to the fifth implementation form of the fifth aspect, two coils of the main winding of the secondary winding are arranged at a top edge of the primary winding.

By such design the magnetic coupling between the primary winding and secondary winding comes from both horizontal and vertical directions. This further improves the coupling factor k between the two windings to promote wideband operation.

According to a sixth aspect, the disclosure relates to a power matching network for use in a digital or analog power amplifier, the power matching network comprising: a transformer according to the fifth aspect as such or according to any of the implementation forms of the fifth aspect; a pair of input capacitances, each input capacitance coupled to a respective port of the primary winding; and an output capacitance coupled between a first port and a second port of the secondary winding.

Such a power matching network can replace the classical class-E matching network thereby minimizing the number of passive components. Only three fixed passive components are needed in this matching network, i.e. input capacitance Cₚ (including parasitic capacitance of switch device), output capacitance Cₒᵤₜ and the SSI transformer. The wideband fundamental resonant tank is absorbed into the power matching network to allow the current of fundamental frequency to pass.

### BRIEF DESCRIPTION OF THE DRAWINGS

Further embodiments of the disclosure will be described with respect to the following figures, in which:

FIG. 1a) shows a schematic diagram illustrating a stepped impedance inductor 100 according to an implementation form;

FIG. 1b) shows a block diagram illustrating the transmission line model 101 of the stepped impedance inductor 100 depicted in FIG. 1a) according to an implementation form;

FIG. 2a) shows a block diagram illustrating the even-mode equivalent circuit diagram 200 of the stepped impedance inductor 100 depicted in FIG. 1a) according to an implementation form;

FIG. 2b) shows a block diagram illustrating the odd-mode equivalent circuit diagram 201 of the stepped impedance inductor 100 depicted in FIG. 1a) according to an implementation form;

FIG. 3 shows a diagram 300 illustrating the quality factor and inductance (small figure) over frequency of different inductor types including the stepped impedance inductor 100;

FIG. 4a) shows a circuit diagram illustrating a stacked stepped impedance transformer 400 according to an implementation form in a 3-dimensional view;

FIG. 4b) shows a circuit diagram illustrating a simplified transmission line model of the primary winding 401 of the SSI transformer 400 depicted in FIG. 4a) according to an implementation form;

FIG. 4c) shows a circuit diagram illustrating a simplified transmission line model of the secondary winding 402 of the SSI transformer 400 depicted in FIG. 4a) according to an implementation form;

FIG. 5 shows a circuit diagram illustrating a digital power amplifier 500 including the SSI transformer 400 depicted in FIG. 4 according to an implementation form;

FIG. 6a) shows a diagram 600a illustrating the coupling factor k over frequency of different transformer types including the SSI transformer 400 depicted in FIG. 4 according to an implementation form;

FIG. 6b) shows a diagram 600b illustrating the inductance ratio over frequency of different transformer types including the SSI transformer 400 depicted in FIG. 4 according to an implementation form;

FIG. 6c) shows a diagram 600c illustrating the passive power efficiency in percent over frequency of different transformer types including the SSI transformer 400 depicted in FIG. 4 according to an implementation form;

FIG. 7 shows a circuit diagram illustrating a digital polar modulator 700 including the SSI transformer 400 depicted in FIG. 4 according to an implementation form;

FIG. 8 shows a circuit diagram illustrating a digital IQ transmitter 800 including the SSI transformer 400 depicted in FIG. 4 according to an implementation form;

FIG. 9 shows a circuit diagram illustrating an analog power amplifier 900 including the SSI transformer 400 depicted in FIG. 4 according to an implementation form; and

FIG. 10 shows a schematic diagram illustrating a method 1000 for producing a transformer according to an implementation form.

### DETAILED DESCRIPTION OF EMBODIMENTS

In the following detailed description, reference is made to the accompanying drawings, which form a part thereof, and in which is shown by way of illustration specific aspects in which the disclosure may be practiced. It is understood that other aspects may be utilized and structural or logical changes may be made without departing from the scope of the present disclosure. The following detailed description, therefore, is not to be taken in a limiting sense, and the scope of the present disclosure is defined by the appended claims.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

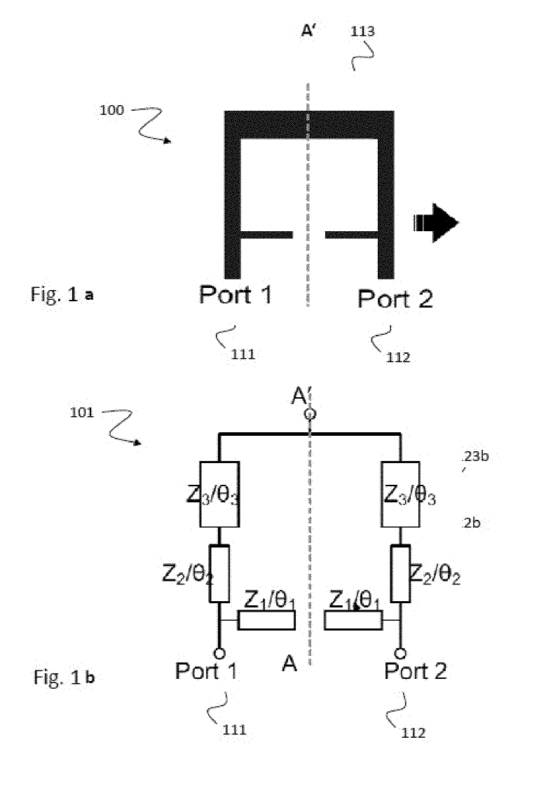

FIG. 1a) shows a schematic diagram illustrating a stepped impedance inductor 100 according to an implementation form and FIG. 1b) shows a block diagram illustrating the transmission line model 101 of the stepped impedance inductor 100.

The stepped impedance inductor 100 includes a first port 111, a second port 112 and a metal layer 113 connected between the first port 111 and the second port 112, the metal layer 113 including a plurality of sections 121a/b, 122a/b, 123a/b of different widths. Each section 121a/b, 122a/b, 123a/b of the plurality of sections of the metal layer 113 may have a different local characteristic impedance and may have a different electrical length. In the example of FIG. 1a), the metal layer 113 is arranged on a single plane. In the example of FIG. 1a), the metal layer 113 is arranged symmetrically with respect to the first port 111 and the second port 112, in particular symmetrically with respect to a perpendicular bisector AA′ of the first port 111 and the second port 112.

In the example of FIG. 1, each section 121a/b, 122a/b, 123a/b includes a first subsection 121a, 122a, 123a and a second subsection 121b, 122b, 123b of the same width, the first subsection 121a, 122a, 123a and the second subsection 121b, 122b, 123b arranged symmetrically with respect to the first port 111 and the second port 112. In the example of FIG. 1, the metal layer 113 includes a branch-off 121a, 121b having a different width than the other sections 122a/b, 123a/b of the metal layer 113.

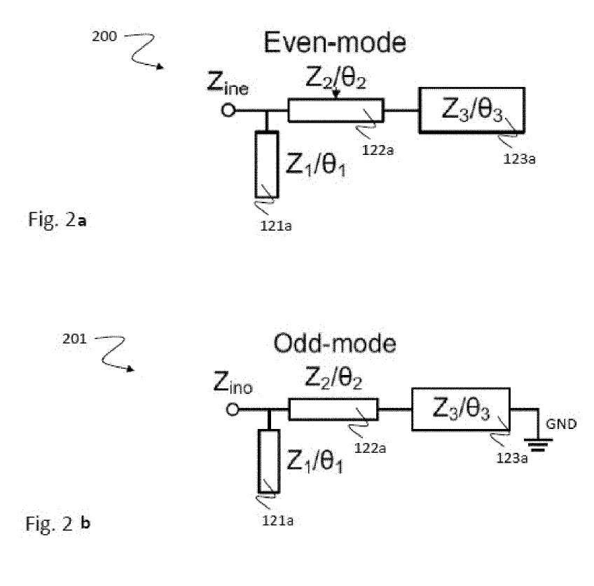

FIG. 2a) shows a block diagram illustrating the even-mode equivalent circuit diagram 200 of the stepped impedance inductor 100 depicted in FIG. 1a) according to an implementation form and FIG. 2b) shows a block diagram illustrating the odd-mode equivalent circuit diagram 201 of the stepped impedance inductor 100 depicted in FIG. 1a) according to an implementation form.

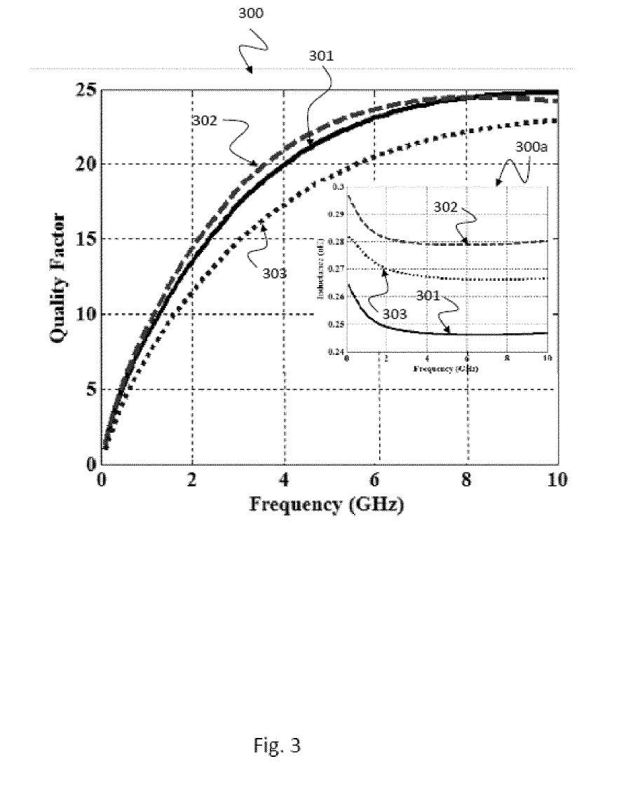

This type of inductor employs segments of different widths (i.e., different local characteristic impedance of Z) with various lengths (i.e., electrical length of θ). The following equations show that, compared to the conventional uniform impedance inductors, the stepped impedance inductor 100 introduces not only more freedom to tune the inductance with the same circuit size, but also achieves an improved Q as illustrated below with respect to FIG. 3.

For the even-mode circuit depicted in FIG. 2a), the input impedance Zᵢₙₑ can be calculated according to equation (1)

$${Z}_{ine} = \frac{- {jZ}_{1} {Z}_{2} ( {Z}_{3} - {Z}_{2} tan {θ}_{2} tan {θ}_{3} )}{{Z}_{2} {Z}_{3} tan {θ}_{1} + {Z}_{1} {Z}_{3} tan {θ}_{2} + {Z}_{1} {Z}_{2} tan {θ}_{3} - {Z}_{2} {E}_{2}} \qquad ( 1 )$$

where

E₂=tan θ₁ tan θ₂ tan θ₃ (2)

For the odd-mode circuit depicted in FIG. 2b), the input impedance Zᵢₙₒ can be calculated according to equation (3):

$$\begin{matrix}{Z}_{ino} = \frac{{jZ}_{1} {Z}_{2} ( {Z}_{3} tan {θ}_{3} + {Z}_{2} tan {θ}_{2} )}{{Z}_{1} {Z}_{2} - {E}_{1}} & ( 3 ) \\ where & \\ {E}_{1} = {Z}_{1} {Z}_{3} tan {θ}_{2} tan {θ}_{3} + {Z}_{2}^{2} tan {θ}_{1} tan {θ}_{2} + {Z}_{2} {Z}_{3} tan {θ}_{1} tan {θ}_{3} & ( 4 )\end{matrix}$$

The characteristic impedance Z₁₁ can be calculated according to equation (5):

$${Z}_{11} = \frac{{Z}_{ino} + {Z}_{ine}}{2} \qquad ( 5 )$$

The quality factor Q can be calculated according to equation (6):

$$Q = \frac{Im ( {Z}_{11} )}{Re ( {Z}_{11} )} \qquad ( 6 )$$

FIG. 3 shows a diagram 300 illustrating the quality factor over frequency of different inductor types including the stepped impedance inductor 100. The first curve 301 depicts the characteristic of a stepped-impedance inductor of type I, the second curve 302 depicts the characteristic of a stepped-impedance inductor of type II and the third curve 303 depicts the characteristic of a conventional inductor of uniform impedance, i.e., having a metal layer of just a single width. The second diagram 300a shows the inductance over frequency characteristic of the respective inductor types. The full-wave EM simulation results depicted in FIG. 3 prove the advantage of higher Q for stepped-impedance inductor 301, 302 compared to conventional uniform-impedance inductor 303.

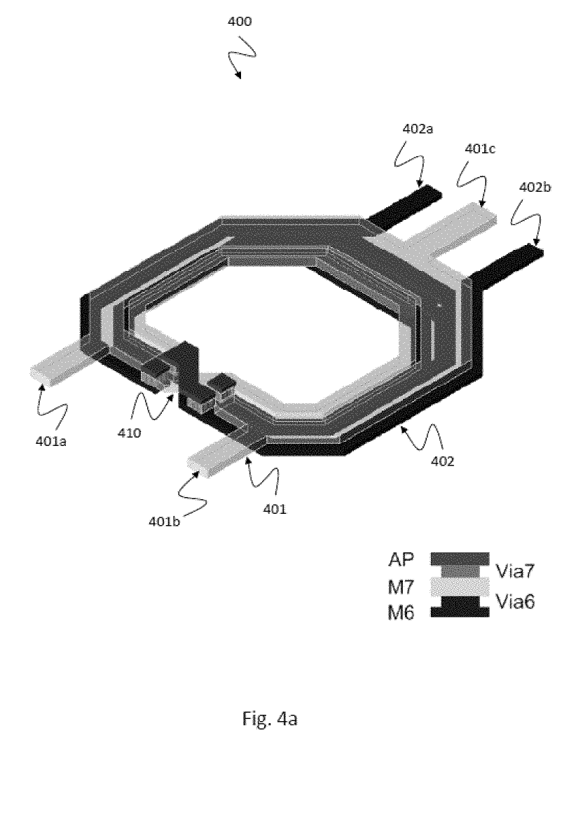

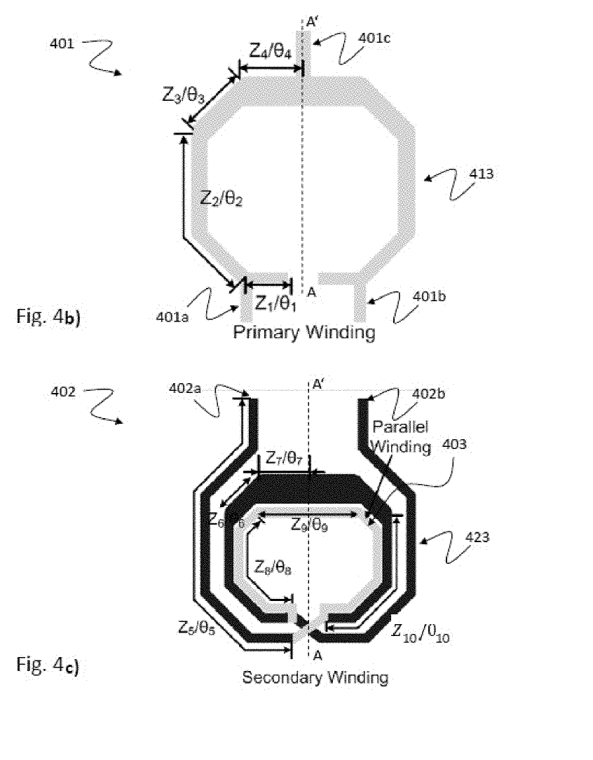

FIG. 4a) shows a circuit diagram illustrating a stacked stepped impedance transformer 400 according to an implementation form in a 3-dimensional view. FIG. 4b) shows a circuit diagram illustrating a simplified transmission line model of the primary winding 401 of the SSI transformer 400 depicted in FIG. 4a) according to an implementation form. FIG. 4c) shows a circuit diagram illustrating a simplified transmission line model of the secondary winding 402 of the SSI transformer 400 depicted in FIG. 4a) according to an implementation form.

The transformer 400 includes a primary winding 401, e.g. implemented as stepped inductor 100 as described above with respect to FIGS. 1-3, and a secondary winding 402, e.g. implemented as stepped inductor 100 as described above with respect to FIGS. 1-3.

The primary winding 401 includes a first port 401a, a second port 401b and a metal layer 413 connected between the first port 401a and the second port 401b, the metal layer 413 including a plurality of sections Z₁/θ₁, Z₂/θ₂, Z₃/θ₃, Z₄/θ₄ of different electrical lengths and characteristic impedances. The secondary winding 402 is electromagnetically coupled with the primary winding 401. The secondary winding 402 includes a first port 402a, a second port 402b and a metal layer 423 connected between the first port 402a and the second port 402b. The metal layer 423 includes multiple sections Z₅/θ₅, Z₆/θ₆, Z₇/θ₇, Z₈/θ₈, Z₉/θ₉, Z₁₀/θ₁₀ of different electrical lengths and characteristic impedances.

Please note that with respect to electrical lengths and characteristic impedances according to the disclosure, the following cases may apply: all Zᵢ are different from each other and all θᵢ are different from each other; the relation Zᵢ/θᵢ, is different for all i; the Zᵢ are the same and the θᵢ are different; the Zᵢ are different and the θᵢ are the same; some of the Zᵢ are the same and some of the θᵢ are different; some of the Zᵢ are different and some of the θᵢ are the same. Any other variation may apply as well.

In the example of FIG. 4, the primary winding 401 and the secondary winding 402 are stacked coupled by having at least a main portion of the secondary winding 402 arranged under or above the primary winding 401. The primary winding 401 and the secondary winding 402 may be planar coupled by having both windings 401, 402 on the same plane.

At least one of the primary winding 401 or the secondary winding 402 may include an auxiliary winding 403 arranged in parallel with the at least one of the primary winding 401 or the secondary winding 402. In the example of FIG. 4a) and FIG. 4c), the primary winding 401 includes the auxiliary winding 403 arranged in parallel with the secondary winding 402.

Each section of the plurality of sections Z₁/θ₁, Z₂/θ₂, Z₃/θ₃, Z₄/θ₄, Z₅/θ₅, Z₆/θ₆, Z₇/θ₇, Z₈/θ₈, Z₉/θ₉, Z₁₀/θ₁₀ of the metal layer 413, 423 of the primary winding 401 and/or the secondary winding 402 may have a different local characteristic impedance Z₁, Z₂, Z₃, Z₄, Z₅, Z₆, Z₇, Z₈, Z₉, Z₁₀. Each section of the plurality of sections Z₁/θ₁, Z₂/θ₂, Z₃/θ₃, Z₄/θ₄, Z₅/θ₅, Z₆/θ₆, Z₇/θ₇, Z₈/θ₈, Z₉/θ₉, Z₁₀/θ₁₀ of the metal layer 413, 423 of the primary winding 401 and/or the secondary winding 402 may have a different or same electrical length θ₁, θ₂, θ₃, θ₄, θ₅, θ₆, θ₇, θ₈, θ₉, θ₁₀.

The metal layer 413 of the primary winding 401 may be arranged on a single plane and/or the metal layer 423 of the secondary winding 402 may be arranged on a single plane. In the example of FIGS. 4a, 4b and 4c, the metal layer 413 of the primary winding 401 is arranged symmetrically with respect to the first port 401a and the second port 401b of the primary winding 401, in particular symmetrically with respect to a perpendicular bisector AA′ (shown in FIG. 4b)/c) of the first port 401a and the second port 401b of the primary winding 401. In the example of FIGS. 4a, 4b and 4c, the metal layer 423 of the secondary winding 402 is arranged symmetrically with respect to the first port 402a and the second port 402b of the secondary winding 402, in particular symmetrically with respect to a perpendicular bisector AA′ of the first port 402a and the second port 402b of the secondary winding 402.

In the example of FIGS. 4a, 4b, 4c, each section Z₁/θ₁, Z₂/θ₂, Z₃/θ₃, Z₄/θ₄ of the metal layer 413 of the primary winding 401 includes a first subsection and a second subsection of the same dimension. The first subsection and the second subsection are arranged symmetrically with respect to the first port 401a and the second port 401b of the primary winding 401. Each section Z₅/θ₅, Z₆/θ₆, Z₇/θ₇, Z₈/θ₈, Z₉/θ₉, Z₁₀/θ₁₀ of the metal layer of the secondary winding 402 includes a first subsection and a second subsection of the same dimension. The first subsection and the second subsection are arranged symmetrically with respect to the first port 402a and the second port 402b of the secondary winding 402.

The metal layer of the auxiliary winding 403 may be arranged on the same metal layer 413, 423 of a main winding of the at least one of the primary winding 401 or the secondary winding 402. The auxiliary winding 403 of the at least one of the primary winding 401 or secondary winding 402 may be arranged inside a main winding of the at least one of the primary winding 401 or the secondary winding 402.

In the example of FIG. 4c), two turns of the main winding of the secondary winding 402 are arranged at a top edge of the main winding of the primary winding 401. Any other number of turns may be used. In the example of FIG. 4b), the metal layer 413 of the primary winding 401 includes sections Z₁/θ₁, Z₂/θ₂, Z₃/θ₃, Z₄/θ₄ of four different electrical lengths and characteristic impedances. Any other number than four may be used. In the example of FIG. 4c), the metal layer 423 of the secondary winding 402 is formed by a main winding of three different characteristic impedances Z₅, Z₆, Z₇ and four different electrical lengths θ₅, θ₆, θ₇, θ₁₀ and a parallel auxiliary winding 403 of two different characteristic impedances Z₈, Z₉ and two different electrical lengths θ₈, θ₉. The main winding of the secondary winding 402 is stacked under the primary winding 401 and the auxiliary winding 403 of the secondary winding 402 located inside the primary winding 401. Any other number of widths and electrical lengths for main and auxiliary windings may be used as well.

In the example of FIG. 4, to improve the transformer's Q-factor, two stepped-impedance inductors are employed to form the primary and secondary windings 401, 402. The primary winding 401 is located at ultra-thick metal M7 with 4 different electrical lengths and characteristic impedances Zₖ/θₖ, k=1, . . . , 4. The secondary winding 402 is formed by two parallel windings 403. One main winding with 4 different characteristic impedances and electrical lengths Z₅/θ₅, Z₆/θ₆, Z₇/θ₇, Z₁₀/θ₁₀ at metal M6 is stacked under the primary winding 401. Meanwhile, a parallel winding 403 with 2 different sections Z₈/θ₈, Z₉/θ₉ at M7 is implemented inside the primary winding 401, thus the magnetic coupling between the primary winding 401 and secondary winding 402 comes from both horizontal and vertical directions. This further improves the coupling factor k between the two windings 401, 402 to promote wideband operation. The total series resistance of the secondary winding 402 is also reduced due to the parallel winding 403 to improve Q. Furthermore, two coils of the secondary main winding 402 are at the top edge of the primary winding 401 to decrease the inter-winding parasitic capacitance.

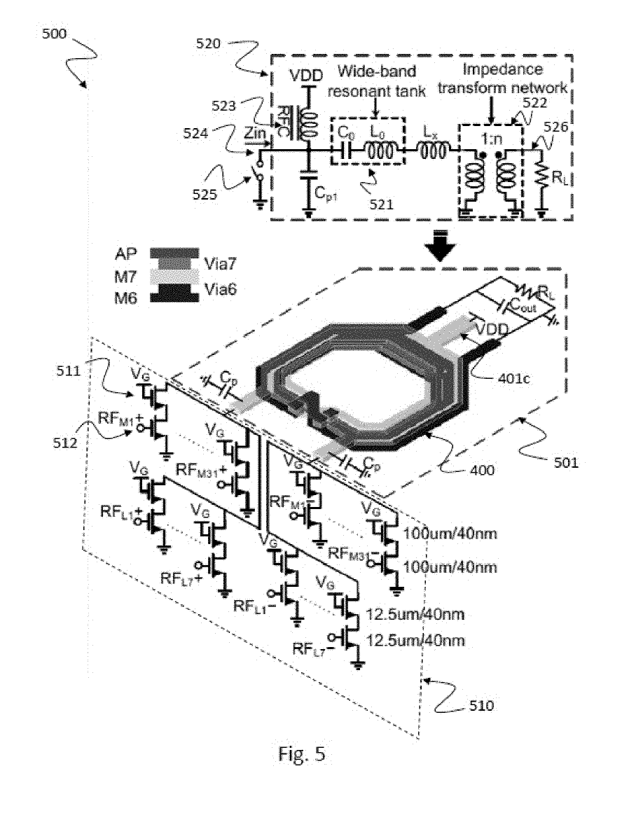

FIG. 5 shows a circuit diagram illustrating a digital power amplifier 500 including the SSI transformer 400 depicted in FIG. 4 according to an implementation form. The digital power amplifier 500 includes a power matching network 501; and a differential cascode switch mode transistor array 502 coupled to the first port 401a and the second port 401b of the primary winding 401. A load R_{L} is connectable to the first port 402a and the second port 402b of the secondary winding 402. The power matching network 501 includes: a transformer 400, e.g. a transformer 400 as described above with respect to FIG. 4; a pair of input capacitances Cₚ, each input capacitance Cₚ coupled to a respective port 401a, 401b of the primary winding 401; and an output capacitance Cₒᵤₜ coupled between a first port 402a and a second port 402b of the secondary winding 402. A driving voltage VDD is connected to a middle section 401c of the primary winding 401. The middle section 401c is located in the middle of the metal layer 413 between the first port 401a and the second port 401b.

The power matching network 501 is an implementation of the class-E matching network 520 with wide-band resonant tank 521 as depicted in the upper part of FIG. 5. Such class-E matching network 520 includes an RF choke 523 coupled between a driving voltage VDD and an input 524 of the class-E matching network 520 that is coupled by a peripheral capacitance Cₚ₁ to ground; the wide-band resonant tank 521 coupled between the input 524 of the class-E matching network 520 and via an auxiliary inductance Lₓ to an input of an impedance transform network 522 and the impedance transform network 522 which output 526 can be coupled to a load R_{L}. The input 524 of the matching network 520 can be coupled to a switching network 525.

The differential cascode switch mode transistor array 502 includes a plurality of radio frequency (RF) switches RF_{M1}⁺, RF_{M31}⁺, RF_{M1}⁻, RF_{M31}⁻, RF_{L1}⁺, RF_{L7}⁺, RF_{L1}⁻, RF_{L7}⁻ connected in parallel. Each radio frequency switch includes a pair of transistors 511, 512 connected in series between a control voltage VG and a ground potential.

FIG. 5 shows an implementation example of the SSI transformer 400 in a digital power amplifier (DPA). The DPA is designed and optimized as class-E to achieve high efficiency. The classical class-E matching network 520 with wide-band resonant tank 521 is converted to the new topology 501 to minimize the number of passive components. Only three fixed passive components are needed in this matching network, i.e. Cₚ (including parasitic capacitance of switch device), Cₒᵤₜ, and the SSI transformer 400. The wide-band fundamental resonant tank 521 (L₀ and C₀) is absorbed into the new network 501 to allow the current of fundamental frequency to pass. The SSI transformer 400 performs the impedance transformation from the optimum load of the active circuits to the 50-ohm antenna load, while combining all the DPA cells current and acting as part of the band-pass matching network. To realize the broad-band DPA with high efficiency and high output power, transformer with low insertion loss and high inductance ratio within a wide operation band are used.

In an example the DPA includes a 8-bit DPA core employing differential cascode switch-mode PA array with 2 segments, for example 5 bits MSB and 3 bits LSB. The optimized load impedance at the drain+node of the DPA array may be maintained at an exemplary value of 6.5+j3 ohm in an exemplary frequency range of 3.5 to 9.5 GHz, e.g. based on a fundamental frequency load-pull simulation prediction. Thus, an inductance ratio of about 3.8 may be chosen for the transformer (50/(2×6.5)).

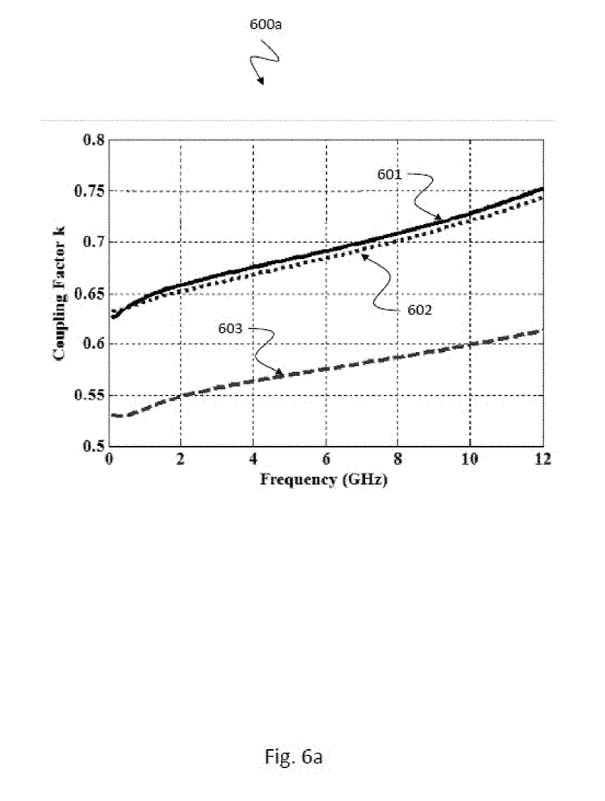

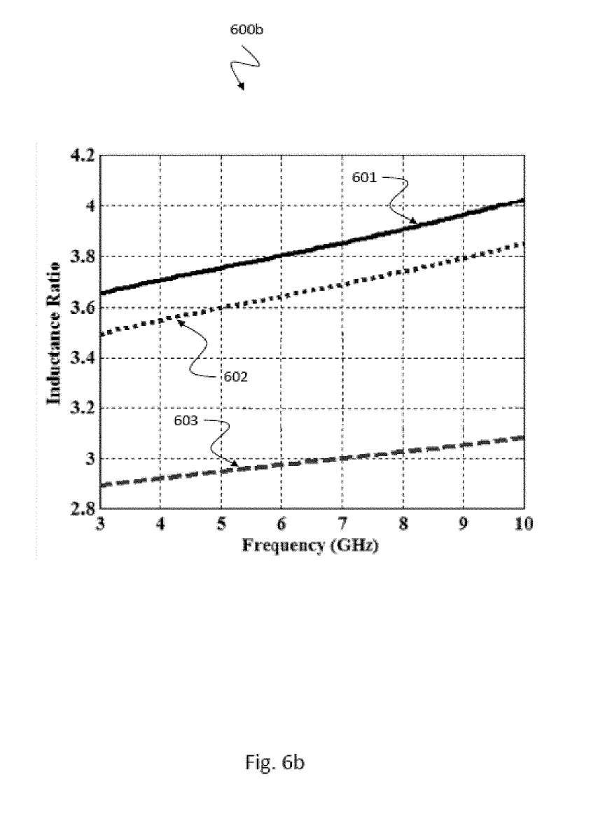

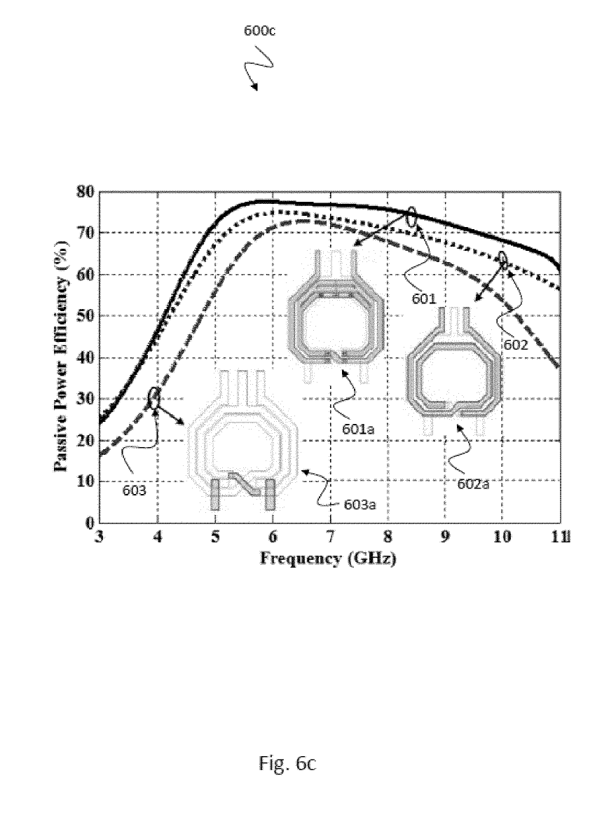

FIG. 6a) shows a diagram 600a illustrating the coupling factor k over frequency of different transformer types including the SSI transformer 400 depicted in FIG. 4 according to an implementation form. FIG. 6b) shows a diagram 600b illustrating the inductance ratio over frequency of different transformer types including the SSI transformer 400 depicted in FIG. 4 according to an implementation form. FIG. 6c) shows a diagram 600c illustrating the passive power efficiency in percent over frequency of different transformer types including the SSI transformer 400 depicted in FIG. 4 according to an implementation form. The curve 601 illustrates the SSI transformer as described above with respect to FIG. 4, the curve 602 illustrates the stacked coupling transformer (without parallel winding and stepped-impedance) and the curve 603 illustrates the planar coupling transformer.

FIGS. 6a/b/c show that the SSI transformer 601 has a higher coupling factor compared to the planar coupling transformer 603 and the stacked coupling transformer 602. With a similar size, SSI transformer 601 also exhibits the merit of higher inductance ratio, thus achieving the design goal of around 3.8 from 3 to 10 GHz. Efficiencies of the total passive matching network 501 (including Cₚ, Cₒᵤₜ and parasitic capacitance of cascode device 510 drain) for the 3 types of transformers are compared. Based on the full-wave EM simulations, the matching network 501 exhibits 77% peak efficiency, exceeding 60% at frequencies above 4.5 GHz. It maintains a wide bandwidth from 3 to 11 GHz.

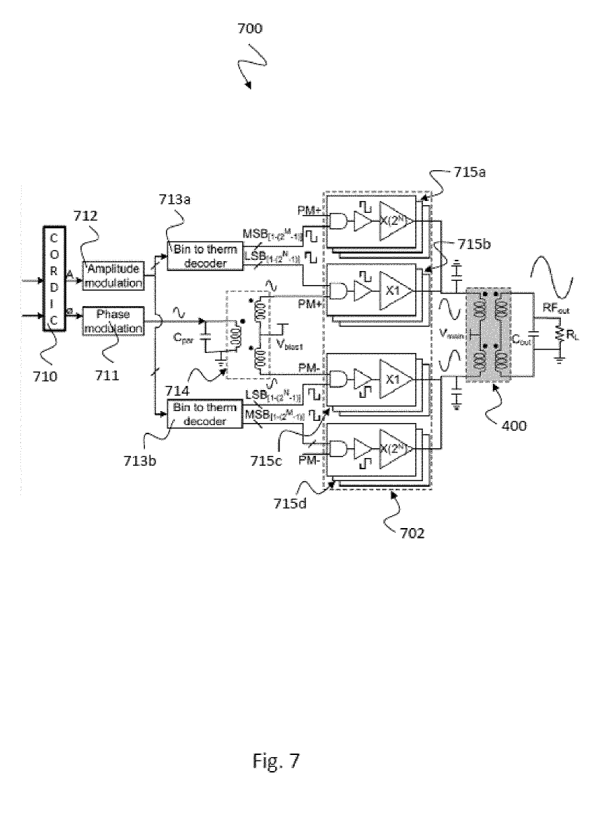

FIG. 7 shows a circuit diagram illustrating a digital polar modulator 700 including the SSI transformer 400 depicted in FIG. 4 according to an implementation form. The digital polar modulator 700 includes a CORDIC unit 710 to provide phase and amplitude of the input signal. The phase is processed by a phase modulator 711, the amplitude by an amplitude modulator 712. The modulated amplitude is passed to thermometer decoders 713a, 713b and the modulated phase signal is passed to an input balun 714. An MSB output of the first thermometer decoder 713a is passed to a first driver and power amplifier array 715a of a driver and amplifier unit 702. An LSB output of the first thermometer decoder 713a is passed to a second driver and power amplifier array 715b of the driver and amplifier unit 702. An MSB output of the second thermometer decoder 713b is passed to a third driver and power amplifier array 715c of the driver and amplifier unit 702. An LSB output of the second thermometer decoder 713b is passed to a fourth driver and power amplifier array 715d of the driver and amplifier unit 702. An output of the driver and amplifier unit 702 is passed to the SSI transformer 400 that may correspond to the SSI transformer described above with respect to FIG. 4.

The digital envelope signal input to the thermometer decoder 713a, 713b controls the DPA switching cells. Two decoders 713a, 713b are employed for the layout symmetrical routing. The phase modulation signal with RF carrier frequency through the input balun 714 produces differential RF signal. Digital AND gates combine the RF carrier and the digital envelope signal to form a square wave vectors, that feed the DPA drivers implemented as class-D amplifiers. The driver 702 is composed of an inverter chain 715a, 715b, 715c, 715d with optimized driving capability for different sizes of DPA unit cell. It is critical for the system efficiency optimization, since its power consumption increases significantly with higher operating frequency. Thus, the driver 702 size for MSB PA cell is 3.5 times of driver for LSB PA cell. The drivers then feed the class-E PA output stages without any inter-stage matching.

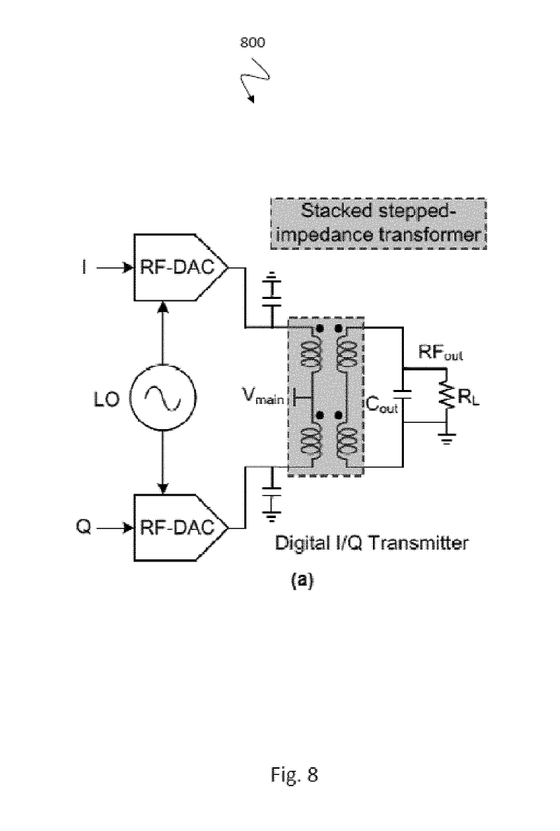

FIG. 8 shows a circuit diagram illustrating a digital IQ transmitter 800 including the SSI transformer 400 depicted in FIG. 4 according to an implementation form. The in-phase part I of an input signal is passed to a first radio frequency digital-to-analog converter RF-DAC 802a controlled by a local oscillator LO. The quadrature part Q of the input signal is passed to a second radio frequency digital-to-analog converter RF-DAC 802b controlled by the same local oscillator LO. Both outputs of the first and second radio frequency digital-to-analog converters RF-DAC 802a, 802b are passed to the inputs of the SSI transformer 400 which outputs are coupled to a load R_{L} in parallel with an output capacitance Cₒᵤₜ. The SSI transformer 400 may correspond to the SSI transformer described above with respect to FIG. 4.

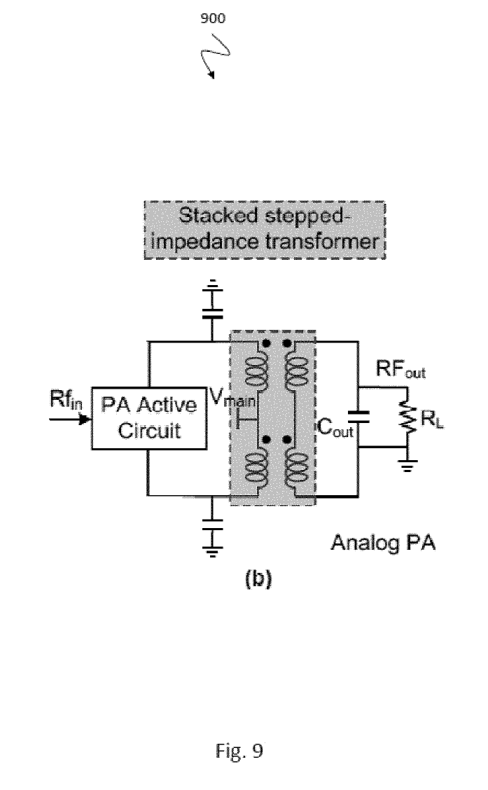

FIG. 9 shows a circuit diagram illustrating an analog power amplifier 900 including the SSI transformer 400 depicted in FIG. 4 according to an implementation form. An input signal RFᵢₙ passes a power amplifier active circuit 902 which outputs are connected to inputs of the SSI transformer 400. Outputs of the SSI transformer 400 are coupled to a load R_{L} in parallel with an output capacitance Cₒᵤₜ. The inputs of the SSI transformer 400 are coupled via capacitances 903a, 903b to ground. The SSI transformer 400 produces an output signal RFₒᵤₜ as power amplified version of the input signal RFᵢₙ. The SSI transformer 400 may correspond to the SSI transformer described above with respect to FIG. 4.

The analog PA 900 with SSI transformer 400 can be of any type of operation classes, for example including class-A, class-B, class-AB, class-C, class-D, class-E, class-E⁻¹, class-F, class-F⁻¹, class-G, etc.

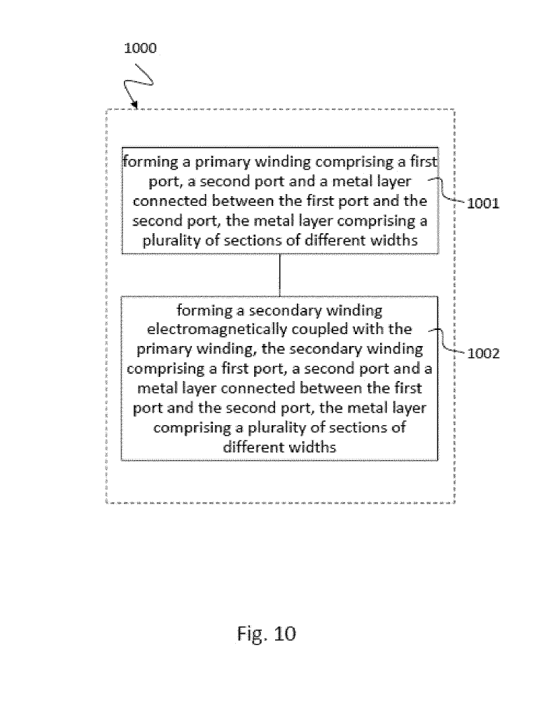

FIG. 10 shows a schematic diagram illustrating a method 1000 for producing a transformer according to an implementation form. The method 1000 includes forming 1001 a primary winding 401 comprising a first port 401a, a second port 401b and a metal layer 413 connected between the first port 401a and the second port 401b, the metal layer 413 comprising a plurality of sections Z₁/θ₁, Z₂/θ₂, Z₃/θ₃, Z₄/θ₄ of different electrical lengths and characteristic impedances. The method 1000 further includes forming 1002 a secondary winding 402 electromagnetically coupled with the primary winding 401, the secondary winding 402 comprising a first port 402a, a second port 402b and a metal layer 423 connected between the first port 402a and the second port 402b, the metal layer 423 comprising a plurality of sections Z₅/θ₅, Z₆/θ₆, Z₇/θ₇, Z₈/θ₈, Z₉/θ₉, Z₁₀/θ₁₀ of different electrical lengths and characteristic impedances.

The method 1000 may include stacked coupling the primary winding and the secondary winding by arranging at least a main portion of the secondary winding under or above the primary winding. The method 1000 may include planar coupling the primary winding and the secondary winding by arranging both windings on the same plane.

The method 1000 may include arranging an auxiliary winding of at least one of the primary winding or the secondary winding in parallel with the at least one of the primary winding or the secondary winding. Each section of the plurality of sections of the metal layer of the primary winding and/or the secondary winding may have a different local characteristic impedance. Each section of the plurality of sections of the metal layer of the primary winding and/or the secondary winding may have a different or same electrical length.

The method 1000 may include arranging the metal layer of the primary winding on a single plane and/or arranging the metal layer of the secondary winding on a single plane.

The method 1000 may include arranging the metal layer of the primary winding symmetrically with respect to the first port and the second port of the primary winding, in particular symmetrically with respect to a perpendicular bisector of the first port and the second port of the primary winding; and/or arranging the metal layer of the secondary winding symmetrically with respect to the first port and the second port of the secondary winding, in particular symmetrically with respect to a perpendicular bisector of the first port and the second port of the secondary winding.

Each section of the metal layer of the primary winding may include a first subsection and a second subsection of the same width. The method 1000 may include arranging the first subsection and the second subsection symmetrically with respect to the first port and the second port of the primary winding.

Each section of the metal layer of the secondary winding may include a first subsection and a second subsection of the same width. The method 1000 may include arranging the first subsection and the second subsection symmetrically with respect to the first port and the second port of the secondary winding.

The method 1000 may include arranging the metal layer of the auxiliary winding on the same metal layer of a main winding of the at least one of the primary winding or the secondary winding. The method 1000 may include arranging the auxiliary winding of the at least one of the primary winding or secondary winding inside a main winding of the at least one of the primary winding or the secondary winding. The method 1000 may include arranging two turns of the main winding of the secondary winding at the top edge of the main winding of the primary winding.

The metal layer of the primary winding may include sections of four different widths. The method 1000 may include forming the metal layer of the secondary winding by a main winding of three different characteristic impedances and four different electrical lengths and a parallel auxiliary winding of two different widths, the main winding of the secondary winding stacked under the primary winding and the auxiliary winding of the secondary winding located inside the primary winding.

The present disclosure also supports a computer program product including computer executable code or computer executable instructions that, when executed, causes at least one computer to execute the performing and computing steps described herein, in particular the method 1000 as described above with respect to FIG. 10 and the techniques described above with respect to FIGS. 1 to 9. Such a computer program product may include a readable storage medium storing program code thereon for use by a computer. The program code may perform the method 1000 as described above with respect to FIG. 10.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the present disclosure. This application is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the disclosure beyond those described herein. While the present disclosure has been described with reference to one or more particular embodiments, those skilled in the art recognize that many changes may be made thereto without departing from the scope of the present disclosure. It is therefore to be understood that within the scope of the appended claims and their equivalents, the disclosure may be practiced otherwise than as specifically described herein.

1. A transformer, comprising:
a primary winding comprising a first port, a second port, and a metal layer connected between the first port of the primary winding and the second port of the primary winding, wherein the metal layer of the primary winding comprises a plurality of sections of different electrical lengths or characteristic impedances; and
a secondary winding electromagnetically coupled with the primary winding, the secondary winding comprising a first port, a second port, and a metal layer connected between the first port of the secondary winding and the second port of the secondary winding, wherein the metal layer of the secondary winding comprises a plurality of sections of different electrical lengths or characteristic impedances.

2. The transformer of claim 1,
wherein the primary winding and the secondary winding are stacked coupled by having at least a portion of the secondary winding arranged under or above a portion of the primary winding.

3. The transformer of claim 1,
wherein the primary winding and the secondary winding are planar coupled by having both windings in a same plane.

4. The transformer of claim 1,
wherein at least one of the primary winding or the secondary winding comprises an auxiliary winding arranged in parallel with the at least one of the primary winding or the secondary winding.

5. The transformer of claim 1,
wherein each section of the plurality of sections of the metal layer of the primary winding or the secondary winding has a different local characteristic impedance.

6. The transformer of claim 1,
wherein each section of the plurality of sections of the metal layer of the primary winding or the secondary winding has a different electrical length.

7. The transformer of claim 1, wherein:
the metal layer of the primary winding is arranged on a single plane; or
the metal layer of the secondary winding is arranged on a single plane.

8. The transformer of claim 1,
wherein the metal layer of the primary winding is arranged symmetrically with respect to a perpendicular bisector of the first port and the second port of the primary winding; or
wherein the metal layer of the secondary winding is arranged symmetrically with respect to a perpendicular bisector of the first port and the second port of the secondary winding.

9. The transformer of claim 8,
wherein each section of the metal layer of the primary winding comprises a first subsection and a second subsection of the same dimension, the first subsection and the second subsection arranged symmetrically with respect to the first port and the second port of the primary winding; or
wherein each section of the metal layer of the secondary winding comprises a first subsection and a second subsection of the same dimension, the first subsection and the second subsection arranged symmetrically with respect to the first port and the second port of the secondary winding.

10. The transformer of claim 4,
wherein the metal layer of the auxiliary winding is arranged on a same metal layer of a main winding of the at least one of the primary winding or the secondary winding.

11. The transformer of claim 4,
wherein the auxiliary winding of the at least one of the primary winding or secondary winding is arranged inside a main winding of the at least one of the primary winding or the secondary winding.

12. The transformer of claim 10,
wherein two turns of the main winding of the secondary winding are arranged at a top edge of the main winding of the primary winding.

13. The transformer of claim 1,
wherein the metal layer of the primary winding comprises sections of four different electrical lengths and characteristic impedances; and
wherein the metal layer of the secondary winding is formed by a main winding of three different characteristic impedances and four different electrical lengths and a parallel auxiliary winding of two different characteristic impedances and two different electrical lengths, the main winding of the secondary winding stacked under the primary winding and the auxiliary winding of the secondary winding located inside the primary winding.

14. A power matching network, the power matching network comprising:
a transformer, comprising:
a primary winding comprising a first port, a second port, and a metal layer connected between the first port of the primary winding and the second port of the primary winding, wherein the metal layer of the primary winding comprises a plurality of sections of different electrical lengths or characteristic impedances; and
a secondary winding electromagnetically coupled with the primary winding, the secondary winding comprising a first port of the secondary winding, a second port of the secondary winding, and a metal layer connected between the first port and the second port, wherein the metal layer of the secondary winding comprises a plurality of sections of different electrical lengths or characteristic impedances;
wherein each input capacitance of a pair of input capacitances is coupled to a respective port of the primary winding; and
wherein an output capacitance is coupled between the first port and the second port of the secondary winding.

15. A digital power amplifier, comprising:
a power matching network comprising a transformer that includes:
a primary winding comprising a first port, a second port, and a metal layer connected between the first port of the primary winding and the second port of the primary winding, wherein the metal layer of the primary winding comprises a plurality of sections of different electrical lengths or characteristic impedances, and
a secondary winding electromagnetically coupled with the primary winding, the secondary winding comprising a first port of the secondary winding, a second port of the secondary winding, and a metal layer connected between the first port and the second port, wherein the metal layer of the secondary winding comprises a plurality of sections of different electrical lengths or characteristic impedances,
wherein each input capacitance of a pair of input capacitances is coupled to a respective port of the primary winding; and wherein an output capacitance is coupled between the first port and the second port of the secondary winding; and
a differential cascode switch mode transistor array coupled to the first port and the second port of the primary winding,
wherein a load is connectable to the first port and the second port of the secondary winding.

16. The transformer of claim 1,
wherein each section of the plurality of sections of the metal layer of the primary winding or the secondary winding has a same local characteristic impedance.

17. The transformer of claim 1,
wherein each section of the plurality of sections of the metal layer of the primary winding or the secondary winding has a same electrical length.
